(19) United States
(12) Patent Application Publication
(10) Pub. No.: US 2011/0220895 A1
(43) Pub. Date: Sep. 15, 2011

(54) THIN FILM TRANSISTOR AND METHOD OF MANUFACTURING THIN FILM TRANSISTOR

(75) Inventors: Katsura Hirai, Tokyo (JP); Makoto Honda, Tokyo (JP); Masaki Miyoshi, Tokyo (JP)

(73) Assignee: KONICA MINOLTA HOLDINGS, INC., Tokyo (JP)

(21) Appl. No.: 13/130,391

(22) PCT Filed: Nov. 10, 2009
(86) PCT No.: PCT/JP2009/069098

§ 371 Date: May 20, 2011

(30) Foreign Application Priority Data
Nov. 27, 2008 (JP) 2008-302200

(51) Int. Cl. H01L 29/786; H01L 21/20

(52) U.S. Cl. 257/57; 257/66; 438/482; 438/488; 257/E21.09; 257/E29.289; 257/E29.292

(57) ABSTRACT

The present invention makes it possible to prepare a thin film transistor fitted with a resin substrate by lowering a process temperature during formation of an oxide semiconductor, and further makes it possible to improve manufacturing efficiency and reduce variations in thin film transistor performance. Disclosed is a thin film transistor of the present invention possessing a semiconductor containing metal oxide, the semiconductor comprising a coating film made from a solution or a dispersion of a precursor, wherein the metal oxide contains indium as a first metal element, gallium or aluminum as a second metal element, and zinc or tin as a third metal element, and a ratio of the third metal element to total metal elements in the metal oxide is 25 at % or less, or 0 at %.

### TECHNICAL FIELD

The present invention relates to a thin film transistor in which an oxide semiconductor is used, with which manufacturing efficiency is improved by making process temperature to be low.

### BACKGROUND

The thin film transistor in which an oxide semiconductor is used is commonly known.

Technologies of thin film transistor (TFT) in which an oxide semiconductor is used is disclosed in Patent Documents 1-3, for example. The TFT in which an oxide semiconductor is used exhibits high performance, but it is formed via vacuum process such as a pulse laser evaporation method, a sputtering method or the like. Further, no resin substrate is usable since process temperature for manufacturing is high. The efficiency of energy caused by high temperature used for formation of a target via sintering is low.

Also known is a method of forming an amorphous oxide semiconductor via decomposition and oxidation (heating and decomposition reaction) of a metal salt or an organic metal. For example, there are methods disclosed in Patent Documents 4 and 5.

In this case, thermal oxidation or plasma oxidation is used for oxidation of a precursor. However, also in cases where oxidation of the precursor is used, desired performance is generally difficult to be achieved unless treating in the very high temperature range of at least 300° C. or of practically at least 400° C. Accordingly, also in this case, it is difficult to be applied to a lightweight and flexible resin substrate or the like since energy efficiency is low; a comparatively long duration of the treatment is consumed; performance tends to be easily varied; and further, the substrate temperature during the treatment as well as the treating temperature rises to the same temperature.

The present invention makes it possible to realize effective production in no vacuum but at normal pressure, whereby process temperature in formation of an oxide semiconductor is lowered, and a device in which a thin film transistor possessing an oxide semiconductor is utilized becomes possible to be applied to the resin substrate.

### PRIOR ART DOCUMENT

### Patent Document

Patent Document 1: Japanese Patent Open to Public Inspection (O.P.I.) Publication No. 2006-165527
Patent Document 2: Japanese Patent O.P.I. Publication. No. 2006-165528
Patent Document 3: Japanese Patent O.P.I. Publication No. 2007-73705
Patent Document 4: Japanese Patent O.P.I. Publication No. 2003-179242
Patent Document 5: Japanese Patent O.P.I. Publication No. 2005-223231

### DISCLOSURE OF THE INVENTION

### Problems to be Solved by the Invention

It is an object of the present invention to enable preparation of a thin film transistor fitted with a resin substrate by reducing process temperature to a low temperature during formation of an oxide semiconductor, and further, not only to improve manufacturing efficiency via lowering of temperature, but also to reduce variations in thin film transistor performance.

### Means to Solve the Problems

The above-described items of the present invention are accomplished by the following structures.

(Structure 1) A thin film transistor comprising a semiconductor comprising metal oxide, the semiconductor comprising a coating film made from a solution or a dispersion of a precursor, wherein the metal oxide comprises indium as a first metal element, gallium or aluminum as a second metal element, and zinc or tin as a third metal element, and a ratio of the third metal element to total metal elements in the metal oxide is 25 at % or less, or 0 at %.

(Structure 2) The thin film transistor of Structure 1, wherein a ratio between the first metal element and the second metal element in the metal oxide is in a range from 1:5 to 5:1.

(Structure 3) The thin film transistor of Structure 1 or 2, wherein the metal oxide comprises one formed via heating of the precursor.

(Structure 4) The thin film transistor of Structure 3, wherein the heating is conducted at a temperature of 100-300° C.

(Structure 5) The thin film transistor of any one of structures 1-4, comprising the metal oxide exposed to microwave during formation of the metal oxide via heating of the precursor.

(Structure 6) The thin film transistor of any one of Structures 1-5, comprising a resin substrate.

(Structure 7) A method of manufacturing a thin film transistor, comprising the steps of forming a semiconductor comprising metal oxide from a coating film made from a solution or a dispersion of a precursor, wherein the metal oxide comprises indium as a first metal element, gallium or aluminum as a second metal element, and zinc or tin as a third metal element, and a ratio of the third metal element to total metal elements in the metal oxide is 25 at % or less, or 0 at %, the method further comprising the step of heating the precursor at a temperature of 100-300° C. to form the thin film transistor.

(Structure 8) The method of Structure 7, wherein the thin film transistor comprises a resin substrate.

### Effect of the Invention

In the present invention, process temperature during formation of an oxide semiconductor can be lowered; manufacturing efficiency can be improved; variations in thin film transistor performance can be reduced; and a thin film transistor fitted with a resin substrate can be prepared.

### BRIEF DESCRIPTION OF THE DRAWINGS

FIGS. 1a, 1b, 1c, 1d, 1e, and 1f each show a diagram showing a typical structure of a thin film transistor element.

FIG. 2 is a schematic equivalent circuit diagram showing an example of a thin film transistor sheet.

FIGS. 3.1, 3.2, 3.3, 3.4, 3.5, 5.6, 3.7, 3.8, 3.9, 3.10, 3.11, 3.12, 3.13 and 3.14 each are a cross-sectional view showing each step to prepare a thin film transistor.

### DESCRIPTION OF THE PREFERRED EMBODIMENTS

In the present invention, disclosed is a thin film transistor possessing a semiconductor containing metal oxide, the semiconductor possessing a coating film made from a solution or a dispersion of a precursor, wherein the metal oxide containing indium as a first metal element, gallium or aluminum as a second metal element, and zinc or tin as a third metal element, and a ratio of the third metal element to total metal elements in the metal oxide is 25 at % or less, or 0 at %.

In the present invention, an oxide semiconductor is formed from a solution or a dispersion of a semiconductor precursor.

Since it is formed via coating, that is, a wet process, no vacuum equipment is used, so that a thin precursor film having uniform film thickness is formed, and further, no large-scale vacuum equipment is needed since it is converted into an oxide semiconductor to form the oxide semiconductor via a heat treatment or the like. Further, like a sputtering method and so forth, an oxide semiconductor can be easily formed without conducting a calcination treatment at high temperature after film formation, whereby a thin film transistor fitted with this oxide semiconductor can be manufactured at comparatively low temperature.

Until now, for example, an In—Ga—Zn—O system amorphous metal oxide semiconductor film has been formed by a vapor deposition method by using a photocrystalline sintered body represented by a composition of InGaO₃(ZnO)ₘ (m=1-5) as a target.

A thin film oxide semiconductor made of an amorphous oxide thereof exhibits high performance in mobility, but a high temperature should be applied since it is conventionally formed by a pulse laser evaporation method, a sputtering method or the like, and further, a very high temperature exceeding 100° C. should be applied during preparation of a target itself. Accordingly, it was difficult to form a semiconductor on a substrate made of a plastic or the like.

Since formation by a wet process is difficult at sufficiently low temperature depending on the configuration of metal compositions or the like, though using the lower temperature than in the case of the above-described sputtering method, a treatment converting into a semiconductor at lower temperature is desired for application to a resin substrate.

It is found out in the present invention that a semiconductor precursor as a coating film is thermally converted into a metal oxide semiconductor via a thermal treatment at 300° C. or less to obtain a metal oxide semiconductor exhibiting high mobility.

It is a feature in the present invention that a thin film transistor possesses a semiconductor containing metal oxide, the semiconductor possessing a coating film made from a solution or a dispersion of a precursor, wherein the metal oxide containing indium as a first metal element, gallium or aluminum as a second metal element, and zinc or tin as a third metal element, and a ratio of the third metal element to total metal elements in the metal oxide is 25 at % or less, or 0 at %.

In, Ga or the like appears to be metal exhibiting a comparatively low melting point, and temperature to be converted into oxide can be lowered. However, Zn or the like appears to be metal exhibiting a comparatively high melting point, and temperature to be converted into oxide also appears to be high. Therefore, the content not more than the foregoing ratio, or no content (=0) appears to be necessary for the precursor to be converted into an oxide semiconductor via a heat treatment at the foregoing comparatively low temperature.

It is further preferable in view of performance of a thin film transistor that a ratio between the first metal element and the second metal element in the foregoing metal oxide is in the range from 1:5 to 5:1.

The ratio of the foregoing metals in the present invention means an atomic concentration ratio of the metals, and may be also called gram atom ratio.

The atomic concentration ratio of metals of an oxide semiconductor can be determined by electron spectroscopy for chemical analysis (ESCA) (for example, an X-ray photoelectron spectrometer ESCA Lab 200R and so forth, manufactured by VG Elemental Inc.).

The electron spectroscopy for chemical analysis is a method by which kinetic energy of photoelectrons released from the surface by exposing a sample thereof to monochromatic X-ray, and a composition of elements present in a depth of several nanometers from the sample surface can be determined qualitatively and quantitatively.

Specifically, measurements were carried out at an output of 600 W (an accelerating voltage of 15 kV, and an emission current of 40 mA) employing Mg as an X-ray anode. The energy resolution was designed so as to be 1.5-1.7 eV when it is specified by a half-value width of a cleaned Ag 3d 5/2 peak.

Measurements were conducted at intervals of 1.0 eV for retrieving data in the binding energy range between 0 eV and 1100 eV to find out what kinds of elements are detected

Next, as to detected elements except etching ions, a narrow-scanning was conducted at intervals of 0.2 eV for retrieving data for a photoelectron peak exhibiting the maximum intensity to measure a spectrum of each element.

After the resulting spectrum is transferred onto Common Data Processing System (preferably one after Ver. 2.3) prepared by VAMAS-SCA-JAPAN in order not to produce difference in result of the calculated content, caused by a different type of measuring device or computer, processing was conducted with the same software to determine the value of content of elements (In, Ga, oxygen and so forth) of each analysis target as atomic concentration: at %.

Before conducting a quantitative process, calibration of the count scale for each element was carried out to conduct 5 point smoothing process. In the quantitative process, peal area intensity (cps*eV) from which the background was removed was used. The Shirley method was used for the background process. In addition, as to the Shirley method, D. A. Shirley, Phys. Rev., B5, 4709 (1972) can be cited.

In the present invention, a coating film formed from a solution or a dispersion made of a semiconductor precursor is placed on a substrate, and a conversion treatment is conducted via thermal oxidation, plasma exposure or the like to convert a precursor material into an oxide semiconductor.

### (Semiconductor Precursor Material)

The semiconductor precursor material means a material converted into a semiconductor layer made of metal oxide via a conversion treatment such as thermal oxidation or the like, and specifically, for example, the following metal atom-containing compounds are cited.

Examples of the metal atom-containing compounds include metal salts, metal halides and organometallic compounds.

Metals of the metal salts, the metal halides and the organometallic compounds include Li, Be, B, Na, Mg, Al, Si, K, Ca, Se, Ti, V, Cr, Mn, Fe, Co, Ni, Cu, Zn, Ga, Ge, Rb, Sr, Y, Zr, Nb, Mo, Cd, In, Ir, Sn, Sb, Cs, Ba, La, Hf, Ta, W, Tl, Pb, Bi, Ce, Pr, Nd, Pm, Eu, Gd, Tb, Dy, Ho, Er, Tm, Yb, Lu and so forth.

Among these metal salts, in the present invention, In may be contained as the first metal, and Ga or Al may be contained as the second metal. Further, either Sn or Zn is designed to be contained, or not to be contained.

For metal salts, nitrate, acetate and so forth are suitably usable, and for halogenated metal compounds, chloride, iodide, bromide and so forth are suitably usable. When using the organometallic compound, those represented by the following Formula (I) are cited.

R¹ₓMR²_{y}R³_{z} Formula (I)

wherein M represents a metal; R¹ represents an alkyl group; R² represents an alkoxy group; and R³ represents a β-diketone ligand, a β-ketocarboxylate ligand, a β-ketocarboxylic acid ligand or a ketooxy group (ketooxy ligand), provided that when the valence of metal M is m, x+y+Z=m where x is an integer of from 0 to m or an integer of from 0 to m−1, y is an integer of from 0 to m, and z is an integer of from 0 to m. Examples of the alkyl group of R¹ include a methyl group, an ethyl group, a propyl group, a butyl group and so forth. Examples of the alkoxy group of R² include a methoxy group, an ethoxy group, a propoxy group, a butoxy group, 3,3,3-trifluoropropoxy group and so forth. The hydrogen atom of the alkyl group may be substituted with a fluorine atom. As to a group selected from the group consisting of the β-diketone ligand, the β-ketocarboxylate ligand, the β-ketocarboxylic acid ligand or the ketooxy group (ketooxy ligand), examples of the β-diketone ligand of R³ include 2,4-pentanedione (acetyl acetone or which is called acetoacetone), 1,1,1,5,5,5-hexamethyl-2,4-pentanedione, 2,2,6,6-tetramethyl-3,5-heptanedione, and 1,1,1-trifluoro-2,4-pentanedione; examples of the β-keto carboxylate ligand of R³ include methyl acetoacetate, ethyl acetoacetate, propyl acetoacetate, ethyl trimethylacetoacetate and methyl trifluoroacetoacetate; examples of the β-ketocarboxylic acid ligand of R³ include acetoacetic acid, and trimethylacetoacetic acid; and examples of the ketooxy group of R³ include an acetoxy group, a propionyloxy group, a butyryloxy group, an acryloyloxy group and a methacryloyloxy group. These groups preferably have 18 carbon atoms or more. Further, those straight-chained or branched may be preferable, and those in which a hydrogen atom is substituted with a fluorine atom may also be preferable. The organometallic compound is preferably one having at least one oxygen atom in the molecule, and more preferably one having, as R², at least one alkoxy group or one having, as R³, at least one of the β-diketone ligand, the β-ketocarboxylate ligand, the β-ketocarboxylic acid ligand and the ketooxy group (ketooxy ligand).

Among metal oxide semiconductor precursors described above, preferable are a metal nitrate, a metal halide and alkoxides. Specific examples thereof include indium nitrate, zinc nitrate, gallium nitrate, tin nitrate, aluminum nitrate, indium chloride, zinc chloride, tin (II) chloride, tin (IV) chloride, gallium chloride, aluminum chloride, indium tri-i-propoxide, zinc diethoxide, bis(dipivaloylmethanato) zinc, tin tetraethoxide, tin tetra-i-propoxide, gallium tri-i-propoxide, aluminum tri-i-propoxide and so forth.

Among the metal salts, a metal nitrate is preferable. The metal nitrate with high purity can be easily obtained and exhibits high solubility to water which is preferably used as a solvent. Examples of the nitrate include indium nitrate, gallium nitrate, aluminum nitrate, tin nitrate, zinc nitrate, tin nitrate and so forth.

### (Film Formation Method of Metal Oxide Semiconductor Precursor Thin Film: Patterning Method)

In the present invention, in order to form a thin film containing metal for the metal oxide semiconductor precursor, a solution in which a precursor material such as a metal salt, a halide, an organometallic compound or the like is dissolved in an appropriate solvent is continuously coated on a substrate. From this viewpoint, as the metal compound, chlorides, nitrates, acetates, metal alkoxides and so forth are preferable in view of solubility. Of these, nitrates are specifically preferable.

Any solvent besides water is used without limitations as long as it dissolves a metal compound, but suitably used are alcohols such as ethanol, propanol, ethylene glycol and so forth; ethers such as tetrahydrofuran, dioxane and so forth; esters such as methyl acetate, ethyl acetate and so forth; ketones such as acetone, methyl ethyl ketone, cyclohexanone and so forth; glycol ethers such as diethylene glycol monomethyl ether and so forth; acetonitrile or the like; aromatic hydrocarbon solvents such as xylene, toluene and so forth; aromatic solvents such as o-dichlorobenzene, nitrobenzene, m-cresol and so forth, aliphatic hydrocarbon solvents such as hexane, cyclohexane, tridecane and so forth; α-terpineol or the like; halogenated alkyl based solvents such as chloroform, 1,2-dichloroethane and so forth; N-methylpyrrolidone or the like; carbon disulfide and so forth.

When at lease one of a metal halide and a metal alkoxide is used, solvents having a relatively high polarity are preferable, and among these, those having a boiling point of 100° C. or less such as water, ethanol, propanol and so forth, acetonitrile or a mixture thereof each are preferably used, and coated on a resin substrate, since it is possible to lower the drying temperature.

When metal alkoxide and a chelating ligand as a multidentate ligand such as alkanol amine, α-hydroxyketone, β-diketone or the like are added in a solvent, the metal alkoxide can be stabilized, and solubility of carboxylic acid salt can be increased. Accordingly, they are preferably added in such an amount that is not adversely affected.

Examples of the method of forming a thin film by providing a solution containing an oxide semiconductor precursor on a substrate include coating methods such as a spin coating method, a spray coating method, a blade coating method, a dip coating method, a cast coating method, a bar coating method, a die coating method and so forth; and coating methods in a broad sense such as letterpress printing, intaglio printing, lithographic printing or screen printing, ink jetting, whereby a patterning method can be also provided via the foregoing method. Further, patterning may be carried out via a photolithographic method, a laser abrasion method or the like for a coating film. Among these, preferable is an ink jet method or a spray coating method which enables thin film coating. Of these, an electrostatic suction type super ink jetting method is preferable since it is possible to finely conduct pattering.

During film formation, a thin film formed from a metal oxide precursor is formed by volatilizing a solution at roughly 150° C. after coating. In addition, it is preferable that a substrate itself has been subjected to heating at roughly 150° C. during dropping of a solution, since two processes of coating and drying can be conducted at the same time

The thin film containing metal as a precursor film has a film thickness of 1-200 nm, and preferably has a film thickness of 5-100 nm.

### (Composition Ratio of Metals)

Accordingly, as to a metal oxide semiconductor of the present invention, it is a feature that the metal oxide possesses indium as the first metal element, gallium or aluminum as the second metal element, and zinc or tin as the third metal element, and a ratio of the third metal element to total metal elements in the metal oxide is 25 at % or less, or 0 at %.

As to the metal oxide, it is preferable that a ratio between the first metal element and the second metal element in the metal oxide is in the range from 1:5 to 5:1.

Of these, the metal oxide semiconductor of the present invention is preferably an In—Ga—O system amorphous metal oxide, and a ratio of Zn to metal elements in the metal oxide is 25 at % or less, and preferably 10 at % or less, or 0 at %.

The formation of oxide would appear because of high thermal oxidation temperature, but an oxide semiconductor exhibiting high mobility is formed at a low calcination temperature of 300° C. or less by adjusting a ratio of the metal in the metal oxide of the precursor in such a way that Zn of the composition ratio in the metal oxide becomes a concentration of 25 at % or less in this manner.

In the case of the concentration exceeding 25 at %, sufficient conversion into metal oxide tends not to be produced.

As metal oxide semiconductors to be formed, any of those which are single-crystalline, polycrystalline and amorphous is usable, but an amorphous thin film is preferably used.

It may be favorably realized that an amorphous oxide as the metal oxide of the present invention, which is formed of metal compound materials to prepare a metal oxide semiconductor precursor has an electron carrier density of less than 10¹⁸/cm³. Herein, the electron carrier density is a value measured at room temperature. The term “room temperature” means, for example, 25° C. Specifically, the room temperature is a certain temperature appropriately selected from a range of 0 to 40° C. In addition, the electron carrier density of the amorphous oxide in the present invention is not required to be less than 10¹⁸/cm³ at the entire range of 0 to 40° C. For example, it may be favorably realized that the electron carrier density is less than 10¹⁸/cm³ at 25° C. A normally off type TFT can be obtained with high yield at a further lower electron carrier density, i.e., at an electron carrier density of preferably 10¹⁷/cm³ or less, and more preferably 10¹⁶/cm³ or less.

The electron carrier concentration can be determined via Hall Effect measurements.

The thickness of the metal oxide semiconductor is not specifically limited, but it is generally 1 μm or less, and preferably from 10-300 nm though the thickness differs depending on kinds of the semiconductor to be used, and properties of the resulting transistor depend largely on the thickness in many cases.

In the present invention, the precursor materials, the composition ratio, and manufacturing conditions are controlled so that the electron carrier concentration falls within the range of, for example, from 10¹²/cm³ to 10¹⁸/cm³. Further, the electron carrier concentration preferably falls within the range of, for example, from 10¹⁵/cm³ to 10¹⁶/cm³.

Since the composition ratio of the precursor and the ratio of the metal composition of the resulting oxide semiconductor do not always coincide with each other, the mixing ratio of the precursor should be adjusted for coating via trial so as to give the foregoing value according to the ratio of the metal oxide after calcination, in order to achieve the foregoing metal ratio of the resulting oxide semiconductor.

In order to convert a precursor material thin film into an oxide semiconductor, a substrate having the precursor material thin film thereon may be heated. When having a structure of the present invention, easy conversion into a semiconductor is made at a temperature of 300° C. or less.

Conversion into an oxide semiconductor by heating a precursor material is made basically via thermal oxidation, and a heat treatment may be conducted in the presence of oxygen such as in the atmosphere.

The heating method is not specifically limited, but as to the forgoing heating, heating may be conducted for 20 minutes to a few hours in the temperature range where a substrate and other elements formed on the substrate are not modified via heat.

When using a resin substrate, heating may be conducted for 20 seconds to 30 minutes, and preferably for 20 minutes to a few hours at 100-300° C., and preferably 180-250° C. Those in the above-described ranges are appropriately selected since the heating conditions (temperature and time) differ depending on the kinds of precursors, the oxygen condition and so forth. Heating is carried out with each of various suitable heating devices, but various electric ovens, a dry heat block, a microwave oven, various heaters and so forth are exemplified. However, the present invention is not limited thereto.

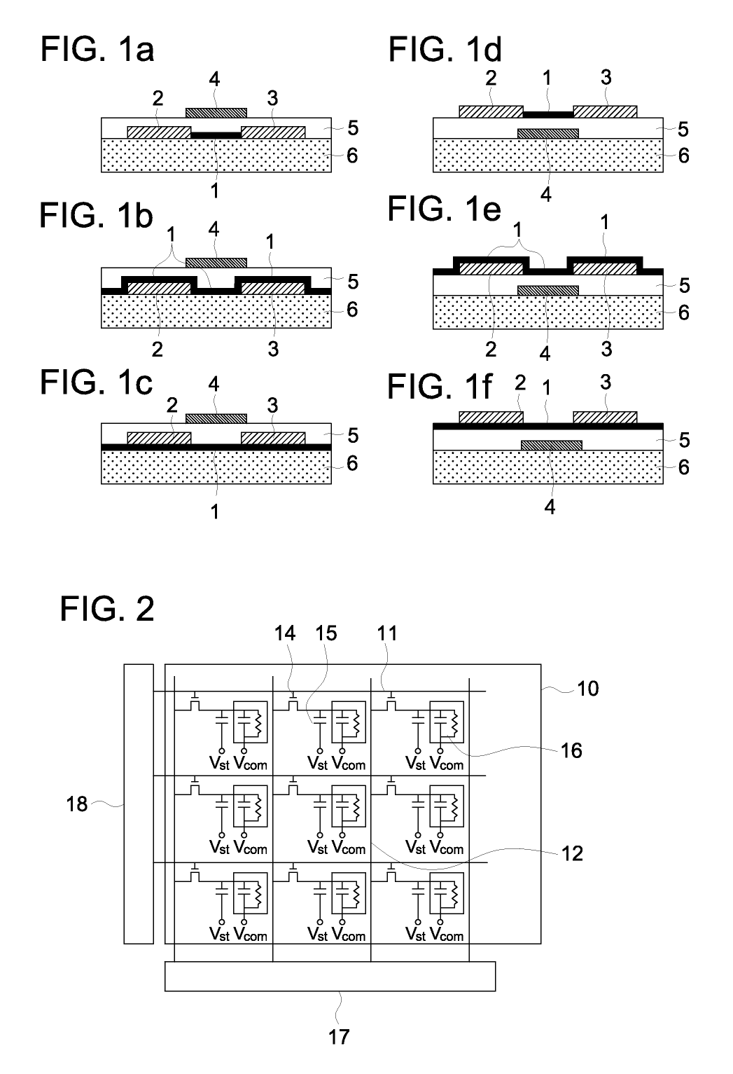

Further, microwave is preferably utilized during the conversion treatment, and a precursor thin film can be heat-treated via heat generation caused by absorption of microwave to convert the precursor material into an oxide semiconductor in the heated region. A precursor thin film or a semiconductor thin film can be heated via exposure to microwave when a material converted from a precursor into metal oxide absorbs the microwave, and a microwave absorption source is placed in the periphery. For example, in the case of the after-mentioned FIG. 1d or the like, when a precursor thin film, a gate electrode and so forth are formed of a microwave absorption material such as, for example, ITO and so forth, not only the precursor thin film and the resulting oxide semiconductor per se generate heat, but also these are exposed to microwave to generate heat, whereby the semiconductor thin film can be heated. The microwave is referred to as electromagnetic waves having a frequency of 0.3-50 GHz.

Temperature of the surface of a thin film, substrate temperature and so forth can be measured with a surface thermometer equipped with a thermocouple or a noncontact surface thermometer.

A precursor material thin film can be converted into a semiconductor layer also by a plasma oxidation method or a method of, for example, conducting a photo-oxidation treatment via exposure to UV light in the presence of oxygen.

Employing such a method, a precursor of the foregoing oxide semiconductor in which temperature to conduct a conversion treatment into metal oxide has been lowered is sufficiently converted into an oxide semiconductor via a heat treatment (calcination) under the mild condition of 300° C. or less.

When temperature to be converted into oxide rises, such a mild heat treatment can not raise mobility of the resulting oxide semiconductor, and for example, mobility of the resulting semiconductor layer is unstably varied a lot, whereby characteristics of a thin film transistor are also varied.

Next, the thin film transistor of the present invention and other elements each constituting a thin film transistor sheet will be described.

The thickness of the semiconductor layer is not specifically limited, and is generally 1 μm or less, and preferably 10-300 nm, although the different thickness is used depending on kinds of the semiconductor, and characteristics of the resulting transistor depend largely on the thickness in many cases.

Next, other elements each constituting the thin film transistor will be described.

### (Electrode)

In the present invention, conductive materials used in the electrodes such as a source electrode, a drain electrode and a gate electrode, which constitute the thin film transistor, are not specifically limited as long as the materials exhibiting conductivity at a practically available level as electrodes. As the conductive materials, utilized are platinum, gold, silver, nickel, chromium, copper, iron, tin, antimony lead, tantalum, indium, palladium, tellurium, rhenium, iridium, aluminum, ruthenium, germanium, molybdenum, tungsten; electrode materials having an electromagnetic wave absorbing capability such as tin-antimony oxide, indium-tin oxide (ITO) or fluorine-doped zinc oxide; zinc, carbon, graphite, glassy carbon, silver paste and carbon paste; lithium, beryllium, sodium, magnesium, potassium, calcium, scandium, titanium, manganese, zirconium, gallium, niobium, sodium, sodium-potassium alloy, magnesium, lithium, aluminum, magnesium/copper mixtures, magnesium/silver mixtures, magnesium/aluminum mixtures, magnesium/indium mixtures, aluminum/aluminum oxide mixtures, lithium/aluminum mixtures, and so forth.

Further, as the conductive materials, conductive polymers or metal particles are preferably usable.

For example, a conductive paste known in the art may be utilized as a dispersion containing metal particles, but the dispersion is preferred which contains metal particles having a particle diameter of 1-50 nm, and preferably 1-10 nm. As a method of fanning an electrode from the metal particles, the method as described can be used, and as materials, the above-described metals are usable.

### (Method of Forming Electrode)

As the method of forming an electrode, there are a method in which the electrode is formed from the conductive materials described above through a mask according to a vacuum deposition method or a sputtering method, a method in which the electrode is formed according to a known photolithography or lift-off method from a conductive layer formed via a vacuum deposition method or a sputtering method, and a method in which a resist is formed on a film of a metal such as aluminum or copper via heat transfer or ink-jet printing, followed by etching. Further, patterning may be directly conducted via an ink-jet printing method using a conductive polymer solution or dispersion or a dispersion containing metal particles, or the electrode may be formed from a coated layer via lithography or laser ablation. Further, it is possible to utilize a method in which the patterning is conducted via a printing method such as letterpress, intaglio, lithographic, screen printing or the like, using a conductive ink, a conductive paste or the like containing a conductive polymer or metal particles.

As a method of forming an electrode such as a source, a drain, a gate electrode or the like, and a gate, a source busline or the like without pattering a metal thin film using a photosensitive resin as in etching or lift-off, there is known one employing an electroless plating method.

In the method of forming electrodes via the electroless plating method, as described in Japanese Patent O.P.I. Publication No. 2004-158805, liquid containing a plating catalyst inducing electroless plating on reaction with a plating agent is patterned on portions where an electrode is provided, for example, via a printing method (including an ink-jet method), followed by allowing the plating agent to be brought into contact with the portions where an electrode is provided. Thus, electroless plating is carried out via contact of the catalyst with the plating agent to form an electrode pattern.

The catalyst and the plating agent may be reversely employed in such electroless plating, and both ways are also allowed to used, but it is preferred to employ a method of forming a plating catalyst pattern to apply a plating agent thereto.

As the printing method, printing such as screen printing, lithographic printing, letterpress printing, intaglio printing or ink jet printing is usable.

As to a electrode material for a source electrode or a drain electrode, and a formation method thereof, it is preferably formed with a fluid electrode material capable of easily forming a film via a wet process such as a coating method, a printing method or the like.

A commonly known conductive paste or the like may be used as a fluid electrode material, but a metal particle dispersion having an average particle diameter of 1-300 nm is preferable. Further, of these, there is provided a nanosized metal particle dispersion as a dispersion containing metal particles having a particle diameter of 1-50 nm, but preferably having a particle diameter of 1-10 nm. Further, a conductive polymer solution, a dispersion and so forth are suitably usable.

Examples of methods of preparing such a metal particle dispersion include a physical preparation method such as an in-gas vaporization method, a sputtering method, or a metallic vapor preparation method and a chemical preparation method such as a colloid method or a co-precipitation method in which metal ions are reduced in a liquid phase to produce metal particles. The metal particle dispersions are preferably ones prepared via a colloid method disclosed in Japanese Patent O.P.I. Publication No. 11-76800, Japanese Patent Publication No. 11-80647, Japanese Patent O.P.I. Publication No. 11-319538, and Japanese Patent O.P.I. Publication No. 2000-239853, or ones prepared via an in-gas vaporization method disclosed in Japanese Patent O.P.I. Publication No. 2001-254185, Japanese Patent O.P.I. Publication No. 2001-53028, Japanese Patent O.P.I. Publication No. 2001-35255, Japanese Patent O.P.I. Publication No. 2000-124157, Japanese Patent O.P.I. Publication No. 2000-123634, and Japanese Patent No. 2561537.

Usable is a method of applying a conductive ink, a conductive paste or the like containing a conductive polymer or metal particles to a printing method such as letterpress, intaglio, lithographic, screen printing or the like.

After applying it onto a substrate via a printing method or the like, fusing is accelerated by conducting a calcination treatment at a temperature of 150-450° C. to realize an electrode exhibiting low resistance.

### (Gate Insulating Layer)

Various insulating films are usable as the gate insulating film of the thin film transistor. An inorganic oxide film exhibiting high dielectric constant is specifically preferable. Examples of the inorganic oxide include silicon oxide, aluminum oxide, tantalum oxide, titanium oxide, tin oxide, vanadium oxide, barium strontium titanate, barium zirconate titanate, lead zirconate titanate, lead lanthanum titanate, strontium titanate, barium titanate, barium magnesium fluoride, bismuth titanate, strontium bismuth titanate, strontium bismuth tantalate, bismuth niobate tantalite and yttrium trioxide. Of these, silicon oxide, aluminum oxide, tantalum oxide or titanium oxide is preferable. Inorganic nitride such as silicon nitride or aluminum nitride is also suitably usable.

As methods for forming the above film, there are mentioned of a dry process such as a vacuum deposition method, a molecular beam epitaxial growth method, an ion cluster beam method, a low energy ion beam method, an ion plating method, a CVD method, a sputtering method, an atmospheric pressure plasma CVD method or the like, and a wet process such as a coating method, for example, a spray coating method, a spin coating method, a blade coating method, a dip coating method, a casting method, a roll coating method, an bar coating method, a die coating method or the like, and a patterning method, for example, a printing method, an ink-jet method or the like. These methods can be suitably applied depending on kinds of materials.

As the typical wet process, used can be a method of coating an inorganic oxide particle dispersion, prepared by dispersing inorganic oxide particles in an organic solvent or water optionally in the presence of a dispersion aid such as a surfactant, followed by drying, or a so-called sol gel method of coating an oxide precursor solution, for example, an alkoxide solution, followed by drying.

Of these, the atmospheric pressure plasma method is preferable.

It is preferred that the gate insulating layer is composed of an anodized oxide film, or composed of the anodized oxide film and an insulating film. The anodized oxide film is preferably subjected to a sealing treatment. The anodized oxide film is formed by anodizing a metal capable of being anodized via a commonly known method.

Examples of the metal capable of being subjected to an anodized oxide treatment include aluminum and tantalum. An anodized oxide treatment method is not specifically limited, and the commonly known methods are usable.

Examples of an organic compound contained in an organic compound layer include polyimide, polyamide, polyester, polyacrylate, photocurable resins of the photo-radical polymerization or photo-cation polymerization type, a copolymer containing an acrylonitrile unit, polyvinyl phenol, polyvinyl alcohol, novolak resin and so forth.

The inorganic oxide layer or the organic oxide layer can be used in combination to be laminated onto each other. The insulating layer generally has a thickness of 50 nm-3 μm, and preferably has a thickness of 100 nm-1 μm.

### (Substrate)

Various materials are usable as substrate materials to constitute a substrate. For example, usable are ceramic substrates such as a glass substrate, a quartz substrate, an aluminum oxide substrate, a sapphire substrate, a silicon nitride substrate, a silicon carbide substrate and so forth; and semiconductor substrates such as a silicon substrate, a germanium substrate, a gallium arsenide and gallium nitride; paper sheets; unwoven cloth sheets and so forth. In the present invention, it is preferred that the substrate is made of a resin. For example, a plastic film sheet is usable. Examples of the plastic film include a polyethylene terephthalate (PET) film, a polyethylene naphthalate (PEN) film, a polyethersulfone (PBS) film, a polyetherimide film, a polyether ether ketone film, a polyphenylene sulfide (PPS) film, a polyallylate, polyimide (PI) film, a Polyamideimide (PAD film, a polycarbonate (PC) film, a cellulose triacetate (TAC) film, a cellulose acetate propionate (CAP) film and so forth. Use of such a plastic film makes it possible to decrease weight, to enhance portability, and to enhance durability against impact, in comparison to a glass substrate.

FIGS. 1a, 1b, 1c, 1d, 1e, and 1f each show a diagram showing a typical structure of a thin film transistor element.

FIG. 1a shows a field-effect thin film transistor in which source electrode 2 and drain electrode 3 are formed on support 6, semiconductor layer 1 is formed between both the electrodes employing the support as a substrate, insulating layer 5 is formed thereon, and gate electrode 4 is further formed on the insulating layer. FIG. 1b shows a field-effect thin film transistor having the same structure as in FIG. 1a, except that semiconductor layer 1 is formed so as to cover the electrodes and the entire surface of the substrate employing a coating process or the like. FIG. 1c shows a field-effect thin film transistor in which semiconductor layer 1 is first formed on support 6, followed by formation of source electrode 2 and drain electrode 3, insulating layer 5, and gate electrode 4.

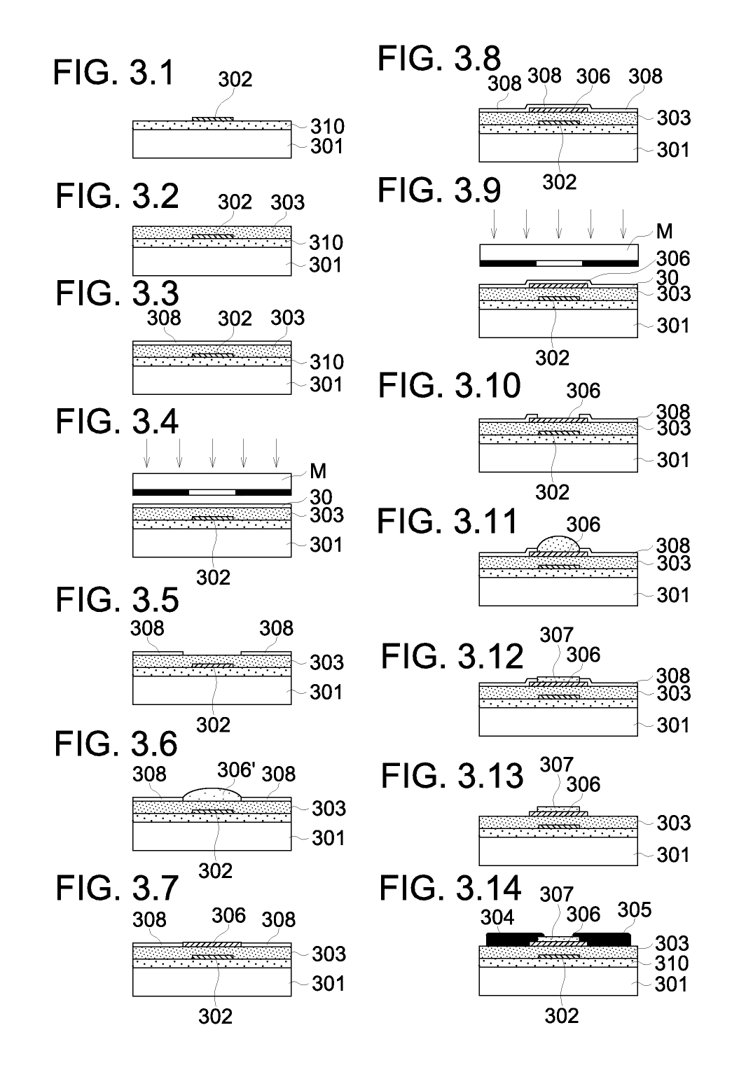

FIG. 1d shows a field-effect thin film transistor in which gate electrode 4 and insulating layer 5 are formed on support 6 to obtain source electrode 2 and drain electrode 3 thereon, and semiconductor layer 1 is formed between both the electrodes. In addition, other field-effect thin film transistors each having a structure are possible to be designed, as shown in FIGS. 3e and 3f.

FIG. 2 shows a schematic equivalent circuit diagram as an example of thin-film transistor sheet 10 as an electronic device in which plural thin film transistor elements are arranged to be placed.

Thin-film transistor sheet 10 possesses a number of thin film transistor elements 14 arranged in the matrix form. Numeral 11 represents a gate busline of the gate electrode of each thin-film transistor element 14, and numeral 12 represents a source busline of the source electrode of each thin-film transistor element 14. Output element 16 is connected to the drain electrode of each thin-film transistor element 14, and output element 16 is, for example, a liquid crystal or an electrophoresis element and constitutes pixels in a display. In an example shown in the figure, liquid crystal as output element 16 is shown in an equivalent circuit diagram composed of a resistor and a capacitor. Numeral 15 represents a storage capacitor, numeral 17 represents a vertical drive circuit, and numeral 18 represents a horizontal drive circuit.

The process of the present invention can be applied for preparation of the thin film transistor sheet in which thin film transistor elements are two-dimensionally arranged to be placed on a substrate.

### EXAMPLE

Next, a method of manufacturing a thin film transistor in which an oxide semiconductor thin film of the present invention is used will be described in detail.

### Example 1

### Preparation of Thin Film Transistor 1

Each step to prepare a thin film transistor in the preferred embodiment of the present invention will be described referring to a cross-sectional view in each of FIGS. 3.1, 3.2, 3.3, 3.4, 3.5, 5.6, 3.7, 3.8, 3.9, 3.10, 3.11, 3.12, 3.13 and 3.14.

A polyimide resin film (200 μm) was used as substrate 301, whose surface was first subjected to a corona discharge treatment under the condition of 50 W/m²/min. Thereafter, a subbing layer was formed to order to improve adhesion as shown below.

### (Formation of Subbing Layer)

A coating solution having the following composition was coated on the substrate, followed by drying at 90° C. for 5 minutes to obtain a dry thickness of 2 μm, and curing was subsequently conducted for 4 seconds at a distance of 10 cm from a high pressure mercury lamp of 60 W/cm.

| | | |
|---|---|---|
| Dipentaerythritolhexaacrylate monomer | 60 | g |
| Dipentaerythritolhexaacrylate dimmer | 20 | g |
| Trimer or more of dipentaerythritolhexaacrylate | 20 | g |
| Diethoxybenzophenone UV initiator | 2 | g |
| Silicone-containing surfactant | 1 | g |
| Methyl ethyl ketone | 75 | g |
| Methylpropylene glycol | 75 | g |

Further, the resulting layer was subjected to an atmospheric pressure plasma treatment under the following conditions to form a silicon oxide film having a thickness of 50 nm, which was designated as subbing layer (barrier layer) 310 (FIG. 3.1).

As an atmospheric pressure plasma treatment apparatus, employed was an apparatus based on FIG. 6 described in Japanese Patent O.P.I. Publication No. 2003-303520.

### (Gas Used)

Inert gas: Helium 9825% by volume

Reactive gas: Oxygen gas 1.5% by volume

Reactive gas: Tetraethoxysilane vapor 0.25% by volume (bubbled with helium gas)

### (Discharge Condition)

Discharge power: 10 W/cm²

### (Electrode Condition)

The electrode was a grounded roll electrode having a dielectric material (specific dielectric constant: 10) with a smooth surface of an Rmax of 5 μm, wherein a stainless steel jacket roll base material having a cooling device employing chilled water was coated with a 1 mm thick alumina layer via ceramic spraying, further coated with a solution prepared by diluting tetramethoxysilane with ethyl acetate, and dried, followed by sealing treatment via ultraviolet irradiation. In contrast, a hollow square-shape stainless pipe having the same dielectric material as above was prepared in the same manner as above, whereby a voltage application electrode was obtained.

Subsequently, formation of a gate electrode was made. A 300 nm thick ITO film was formed entirely on the surface thereof by a sputtering method, followed by etching via photolithography, to form gate electrode 302 (FIG. 3.1). Next, a 180 nm thick silicon oxide film was further provided at a film temperature of 200° C. by the above-described atmospheric pressure plasma method to form gate insulating layer 303 (FIG. 3.2).

Next, a substrate was immersed for 10 minutes in a toluene solution (0.1% by weight at 60° C.) in which octyltrichlorosilane (C₈H1₇SiCl₃) (OTS) was dissolved, followed by rinsing with toluene, surface-treating in an ultrasonic cleaner for 10 minutes, and drying to conduct a surface treatment via reaction of the entire surface of the gate insulating layer with OTS. A monomolecular film is formed with octyltrichlorosilane via the surface treatment, but in the figure, the monomolecular film is represented by surface treatment layer 308 for descriptive purposes (FIG. 3.3).

A Si wafer having been subjected to this surface treatment was exposed to UV light having a wavelength of 254 nm from a low pressure lamp via photomask M possessing a light transmission portion corresponding to a semiconductor channel region (FIG. 3.4). By doing this, the surface of the portion exposed to light was decomposed, whereby the surface treatment portion was hydrophilized. Washing was carded out with ethanol, and the decomposed matter was removed therefrom to expose the surface of gate insulating layer 303 as a portion corresponding to a channel region (FIG. 3.5).

Next, one in which indium nitrate, gallium nitrate and zinc nitrate were mixed so as to realize 1:1:1 in metal ratio of each of the resulting oxides (gram atom ratio) to obtain 10% by weight of an aqueous solution (containing 5% by weight of ethanol) was used as ink, and the ink was ejected along the semiconductor layer pattern (approximately, gate electrode pattern) via piezo-type ink jetting to form precursor material thin film 306′ of a semiconductor (FIG. 3.6). As to the salt ratio of the aqueous solution, indium nitrate, gallium nitrate and zinc nitrate were mixed so as to roughly give 1:0.5:1 in molar ratio.

In addition, the metal ratio of the resulting semiconductor film was determined with an X-ray photoelectron spectrometer ESCA Lab 200R, manufactured by VG Elemental Inc.

The resulting precursor material thin film 306′ having been subjected to a heat treatment at 100° C., followed by drying had an average film thickness of 30 nm.

Further, the resulting one was exposed to microwave from the substrate side. That is, it was exposed to microwave having a frequency of 2.45 GHz at 500 W under the conditions of atmospheric pressure, and 1:1 as partial pressures of oxygen and nitrogen to conduct a treatment at 200° C. for 20 minutes. The precursor material was converted into an oxide semiconductor via heat generation caused by microwave absorption of ITO (gate electrode 302), whereby oxide semiconductor layer 306 was formed on the gate insulating film, facing the gate electrode (FIG. 3.7). Further, prepared were those treated at heating temperatures of 150° C., 250° C. and 300° C., respectively, by adjusting the microwave power. The surface temperature was measured with a surface thermometer equipped with a thermocouple.

Further, a substrate was immersed for 10 minutes in a toluene solution (0.1% by weight at 60° C.) in which octyltrichlorosilane (C₈H1₇SiCl₃) (OTS) was dissolved, followed by rinsing with toluene, surface-treating in an ultrasonic cleaner for 10 minutes, and drying to form a monomolecular film and to conduct a surface treatment via reaction of the surface of the resulting oxide semiconductor layer 306 with OTS. This monomolecular film is similarly represented by surface treatment layer 308 (FIG. 3.8).

Next, a protective film formation region was exposed to UV light having a wavelength of 254 nm employing a mask to cover the region other than the protective film formation region on the semiconductor layer (FIG. 3.9). Surface treatment layer 308 for the protective film formation region on the semiconductor layer was decomposed to expose the semiconductor layer. In addition, since the width of the protective film forms a channel length (distance between source electrode 304 and drain electrode 305), the region exposed to light is adjusted so as to realize a protective film width of 15 μm to expose only the channel region of the semiconductor layer (FIG. 3.10).

Next, a perhydropolysilazane {AQUAMICA NP110 (Registered Trademark), produced by AZ Electronic Materials Co., Ltd.} xylene solution was applied onto the predetermined region on oxide semiconductor 306, employing the same piezo-type ink jet apparatus as described before (FIG. 7.11). Next, the resulting one was exposed to microwave similarly to the foregoing; subjected to a heat treatment in the range of 150-500° C. but actually at 200° C. for about 20 minutes via heat generation of the gate electrode; and converted into a silicon dioxide thin film layer to form protective layer 307 (FIG. 3.12). The protective layer had a thickness of 200 nm.

Next, an oxygen plasma treatment was conducted under the following conditions employing the same atmospheric pressure plasma apparatus as described before to decompose the remaining surface treatment layer 308, whereby a part of the surface of gate insulating layer 303 and oxide semiconductor layer 306 was exposed (FIG. 3.13).

### (Gas Used)

Inert gas: Nitrogen gas 98% by volume

Reactive gas: Oxygen gas 2% by volume

### (Discharge Condition)

High frequency power supply: 13.56 MHz

Discharge power: 10 W/cm²

Next, a silver particle dispersion having a silver content of 20% by weight (CCI-300, produced by Cabot Corporation) was ejected with a piezo-type ink jet head to conduct printing in source electrode and domain electrode portions including exposed regions of the semiconductor layer. Subsequently, a heat treatment was conducted at 200° C. for 30 minutes to form source electrode 304 and drain electrode 305 (FIG. 2.14). Each size possesses a width of 40 μm, a length of 100 μm (channel width) and a thickness of 100 nm, and the distance between source electrode 304 and drain electrode 305 (channel length) was set to 20 μm.

Each of four thin film transistors as thin film transistor 1 for which thermal conversion treatment temperature was changed was prepared by the above-described method.

### (Preparation of Thin Film Transistors 2-6)

Used was a mixed solution obtained by adjusting an amount of each of indium nitrate, gallium nitrate and zinc nitrate in such a way that the metal ratio of each of the resulting oxides (gram atom ratio) became each ratio shown in Table 1 in terms of a ratio of each of indium, gallium and zinc for formation of the semiconductor I Example 1 to form precursor thin films, and each sample was subsequently subjected to a treatment in which heating temperature was changed to each of a temperature of 150° C., a temperature of 200° C., a temperature of 250° C., and a temperature of 300° C. by further adjusting microwave output power to prepare semiconductor layers in the same manner as before, whereby four thin film transistors were prepared as each of thin film transistors 2-6.

In addition, the metal ratio of each of the resulting semiconductor films was determined with an X-ray photoelectron spectrometer ESCA Lab 200R, manufactured by VG Elemental Inc. Further, the temperature was measured with a surface thermometer equipped with a thermocouple.

As to the resulting thin film transistor described above, increase of the drain current (transfer characteristic) was observed by setting the drain bias to 10 V, and sweeping the gate bias from −30 V to +30 V to estimate mobility (cm²/Vs) from a saturation region thereof. Gate voltage Vg (ON) at a rise of the drain current and value of common logarithm (on/off ratio) of a ratio between the maximum value of the drain current and the minimum value of the drain current are evaluated, and these results are shown in Table 1.

TABLE 1

| | | | | Mobility (cm²/Vs) | | | | |
|---|---|---|---|---|---|---|---|---|
| | | | | Vg (ON) | | | | |
| | | | | on/off ratio | | | | |
| Thin film | | Zn ratio | Ga ratio | Heat treatment temperature | | | | |
| transistor | In:Ga:Zn | (%) | (%) | 150° C. | 200° C. | 250° C. | 300° C. | Remarks |
| 1 | 1:1:1 | 33 | 33 | No | 0.0001 | 0.02 | 0.1 | Comparative |
| | | | | operation | −40 | −36 | −30 | example |
| | | | | | 3.5 | 4 | 4.3 | |
| 2 | 1:1:0.5 | 20 | 40 | 0.01 | 0.1 | 0.2 | 0.5 | Present |
| | | | | −15 | −10 | −12 | −17 | invention |
| | | | | 4.7 | 5.3 | 5.7 | 6 | |
| 3 | 1:1:0.1 | 4.8 | 48 | 0.1 | 0.5 | 1.0 | 2.5 | Present |
| | | | | −8 | −5 | −8 | −15 | invention |
| | | | | 5.5 | 6 | 6.5 | 6.3 | |
| 4 | 1:1:0 | 0 | 50 | 0.8 | 3 | 4.7 | 8.0 | Present |
| | | | | −3 | 0 | −5 | −15 | invention |
| | | | | 7.5 | 7.5 | 7.5 | 6.8 | |
| 5 | 1:2:0 | 0 | 67 | 0.1 | 0.3 | 1.0 | 1.2 | Present |
| | | | | −1 | 0 | −2 | −8 | invention |
| | | | | 6.2 | 6.5 | 6.8 | 6.5 | |
| 6 | 1:0.5:0 | 0 | 33 | 0.5 | 0.6 | 1.2 | 2.5 | Present |
| | | | | −8 | −10 | −15 | −20 | invention |
| | | | | 5 | 5.2 | 4.8 | 4.4 | |

The thin film transistors each in which Zn ratio falls within the range of the present invention in the semiconductor exhibit high mobility, excellent operation and n-type enhancement operation. However, those in which the Zn ratio falls outside the range of the present invention exhibit low mobility even though conducting a heat treatment at a temperature of 250° C. as well as a heat treatment at a temperature of 200° C., and one having been subjected to a heat treatment at 180° C. has not been operated at all.

As described above, it is to be understood that those in which the Zn ratio falls within the range of the present invention form semiconductor layers each exhibiting high mobility even though conducting a heat treatment at low temperature.

### Example 2

### Preparation of Thin Film Transistor 7

The thin film transistor was prepared similarly to preparation of the foregoing thin film transistor 4, except that as to a calcination method of a precursor thin film, exposure to microwave was replaced by heating with an oven, and evaluations thereof were made. The results are shown in Table 2.

TABLE 2

| | | | | Mobility (cm²/Vs) | | | | |
|---|---|---|---|---|---|---|---|---|
| | | | | Vg (ON) | | | | |
| | | | | on/off ratio | | | | |
| Thin film | | Zn ratio | Ga ratio | Heat treatment temperature | | | | |
| transistor | In:Ga:Zn | (%) | (%) | 150° C. | 200° C. | 250° C. | 300° C. | Remarks |
| 7 | 1:1:0 | 0 | 50 | 0.01 | 0.03 | 0.08 | 0.3 | Heating |
| | | | | −20 | −18 | −18 | −25 | with oven |
| | | | | 4.1 | 4.8 | 4.9 | 5.2 | Present |
| | | | | | | | | invention |

It was found out that the thin film transistor exhibited excellent operation in view of mobility, Vg and on/off ratio.

### Example 3

### Preparation of Thin Film Transistor 8

The thin film transistors were prepared similarly to preparation of the foregoing thin film transistor 1, except that a heat treatment was conducted at 250° C. for 20 minutes via exposure to microwave having a frequency of 2.45 GHz at an output power of 500 W, and a composition of the metal oxide film was replaced by the following, and evaluations thereof were made.

Indium nitrate, gallium nitrate and tin chloride were mixed so as to realize 1:1:0.1 in metal ratio of each of the resulting oxides (gram atom ratio), and dissolved in a solvent in which acetonitrile, ethanol and water mixed in weight ratio of 2:1:3 to prepare a solution having a content of 10% by weight. This solution was used as ink, and the ink was ejected along the semiconductor layer pattern (approximately, gate electrode pattern) via piezo-type ink jetting to form precursor material thin film 306′ of a semiconductor (FIG. 3.6). As to the salt ratio of the solution, indium nitrate, gallium nitrate and tin chloride were mixed so as to roughly give 1:0.5:0.1 in molar ratio.

The thin film transistor calcined at 250° C. via microwave had a mobility of 0.1 cm²/Vs, a Vg (ON) of −7 V, and an on/off ratio of 5.3.

### (Preparation of Thin Film Transistor 9)

The thin film transistors were prepared similarly to preparation of the foregoing thin film transistor 1, except that a heat treatment was conducted at 250° C. for 20 minutes via exposure to microwave having a frequency of 2.45 GHz at an output power of 500 W, and a composition of the metal oxide film was replaced by the following, and evaluations thereof were made.

Indium nitrate, aluminum nitrate and zinc nitrate were mixed so as to realize 1:1:1 in metal ratio of each of the resulting oxides (gram atom ratio) to prepare an aqueous 10% by weight solution (containing 5% by weight of ethanol). This solution was used as ink, and the ink was ejected along the semiconductor layer pattern (approximately, gate electrode pattern) via piezo-type ink jetting to form precursor material thin film 306′ of a semiconductor (FIG. 3.6). As to the salt ratio of the solution, indium nitrate, aluminum nitrate and zinc nitrate were mixed so as to roughly give 1:0.5:0.1 in molar ratio.

The thin film transistor calcined at 250° C. via microwave had a mobility of 0.07 cm²/Vs, a Vg (ON) of 0 V, and an on/off ratio of 4.8.

The results are shown in Table 3.

TABLE 3

| | | | | Mobility (cm²/Vs) | |
|---|---|---|---|---|---|
| | | | | Vg (ON) | |
| Thin | | Sn | Ga | on/off ratio | |
| film | Metal | or Zn | or Al | Heat treatment | |
| tran- | element | ratio | ratio | temperature | |
| sistor | ratio | (%) | (%) | 250° C. | Remarks |
| 8 | In:Ga:Sn = 1:1:0.1 | 4.8 | 48 | 0.1 | Present |
| | | | | −7 | invention |
| | | | | 5.3 | |
| 9 | In:Al:Zn = 1:1:0.1 | 4.8 | 48 | 0.07 | Present |
| | | | | 0 | invention |
| | | | | 4.8 | |

### EXPLANATION OF NUMERALS

1 Semiconductor layer
2 Source electrode
3 Drain electrode
4 Gate electrode
5 Gate insulating layer
6 Support
10 Thin film transistor sheet
11 Gate busline
12 Source busline
14 Thin film transistor element
15 Storage capacitor
16 Output element
17 Vertical drive circuit
18 Horizontal drive circuit
306′ Precursor material thin film
301 Substrate
302 Gate electrode
303 Gate insulating layer
304 Source electrode
305 Drain electrode
306 Oxide semiconductor layer

1. A thin film transistor comprising a semiconductor comprising metal oxide, the semiconductor comprising a coating film made from a solution or a dispersion of a precursor,
wherein the metal oxide comprises indium as a first metal element, gallium or aluminum as a second metal element, and zinc or tin as a third metal element, and
a ratio of the third metal element to total metal elements in the metal oxide is 25 at % or less, or 0 at %.

2. The thin film transistor of claim 1,
wherein a ratio between the first metal element and the second metal element in the metal oxide is in a range from 1:5 to 5:1.

3. The thin film transistor of claim 1,
wherein the metal oxide comprises one formed via heating of the precursor.

4. The thin film transistor of claim 3,
wherein the heating is conducted at a temperature of 100-300° C.

5. The thin film transistor of claim 1, comprising
the metal oxide exposed to microwave during formation of the metal oxide via heating of the precursor.

6. The thin film transistor of claim 1, comprising a resin substrate.

7. A method of manufacturing a thin film transistor, comprising the steps of:
forming a semiconductor comprising metal oxide from a coating film made from a solution or a dispersion of a precursor,
wherein the metal oxide comprises indium as a first metal element, gallium or aluminum as a second metal element, and zinc or tin as a third metal element, and
a ratio of the third metal element to total metal elements in the metal oxide is 25 at % or less, or 0 at %, the method further comprising the step of:
heating the precursor at a temperature of 100-300° C. to form the thin film transistor.

8. The method of claim 7,
wherein the thin film transistor comprises a resin substrate.
